(19) United States
(12) Patent Application Publication
(10) Pub. No.: US 2026/0353896 A1
(43) Pub. Date: Nov. 5, 2026

(54) LED BEAD, PREPARATION METHOD AND ELECTRONIC DEVICE

(71) Applicant: GUANGDONG OPSCO TECHNOLOGY CO., LTD, Dongguan (CN)

(72) Inventors: MINGJIAN LIU, Dongguan (CN); GENGSHENG ZHU, Dongguan (CN); ZHENLEI WU, Dongguan (CN)

(21) Appl. No.: 19/712,015

(22) Filed: Jun. 18, 2026

Related U.S. Application Data
(63) Continuation of application No. PCT/CN2024/134995, filed on Nov. 27, 2024.

(30) Foreign Application Priority Data
May 14, 2024 (CN) 2024105949948

(51) Int. Cl. H10H 29/853; H10H 20/857; H10H 29/24

(52) U.S. Cl. CPC H10H 29/853; H10H 20/857; H10H 29/24

(57) ABSTRACT

An LED bead, a preparation method, and an electronic device are provided. The LED bead includes an insulating base, pins, a first light-emitting assembly, a second light-emitting assembly, and encapsulation adhesive. The pins are disposed on the insulating base. The first light-emitting assembly is disposed on the pins. The second light-emitting assembly is disposed on the pins. The encapsulation adhesive is configured to encapsulate the first light-emitting assembly and the second light-emitting assembly. The encapsulation adhesive includes a first light-emitting surface disposed relative to the first light-emitting assembly and a second light-emitting surface disposed relative to the second light-emitting assembly.

### CROSS-REFERENCE TO RELATED APPLICATIONS

This application claims the priority of Chinese Patent Application No. 2024105949948 entitled “LED bead, preparation method and electronic device” filed with China National Intellectual Property Administration on May 14, 2024, the entire contents of which are incorporated herein by reference.

### TECHNICAL FIELD

The present disclosure relates to the field of LED technology, and in particular, to an LED bead, a preparation method, and an electronic device.

### BACKGROUND

LED beads have been widely used in the lighting and display industries due to their advantages such as energy saving, power saving, high efficiency, fast response time, long service life, mercury-free and environmental friendliness, and have become one of the most prominent products in recent years.

However, when LED beads are used in relatively narrow areas of electronic products, such as in fans with an annular housing, existing LED beads can only illuminate one side of the fan, which limits the functions of the fan. Meanwhile, with the miniaturization of existing LED bead products—such as during the research and development of ultra-thin screens like grid screens—LED beads need to be arranged in pairs to achieve dual-sided light emission of the products, which restricts further miniaturization of LED products.

### SUMMARY OF THE INVENTION

The present disclosure provides an LED bead, a preparation method and an electronic device, aiming to solve the problem that arranging LED beads in pairs to achieve dual-sided light emission of products restricts the miniaturization of LED products. The LED bead can be provided with a first light-emitting surface and a second light-emitting surface on two sides respectively, so as to achieve flexible dual-sided light emission of the LED bead, and enable the miniaturization of the electronic device designed based on the provided LED bead.

According to a first aspect of the present disclosure, the present disclosure provides a method for preparing an LED bead. The LED bead includes an insulating base, a plurality of pins, a first light-emitting assembly, a second light-emitting assembly and encapsulation adhesive; the plurality of pins are disposed on the insulating base; the first light-emitting assembly includes a first light-emitting chipset and a first driving chip, the first light-emitting chipset and the first driving chip are respectively disposed on the pins and electrically connected to the pins, and the first driving chip is electrically connected to the first light-emitting chipset; the second light-emitting assembly includes a second light-emitting chipset and a second driving chip, the second light-emitting chipset and the second driving chip are respectively disposed on the pins and electrically connected to the pins, and the second driving chip is electrically connected to the second light-emitting chipset; the encapsulation adhesive is configured to encapsulate the first light-emitting assembly and the second light-emitting assembly, the encapsulation adhesive includes a first light-emitting surface and a second light-emitting surface, the first light-emitting surface is disposed relative to the first light-emitting assembly, the second light-emitting surface is disposed relative to the second light-emitting assembly, and the encapsulation adhesive includes a light-transmissive adhesive layer and an opaque adhesive layer; the method includes:
forming the light-transmissive adhesive layer on the outer sides of the first light-emitting assembly and the second light-emitting assembly by a first molding process;
determining a shape of a first adhesive layer corresponding to the first light-emitting assembly based on a first position of the first light-emitting surface in the light-transmissive adhesive layer, wherein the first adhesive layer is the light-transmissive adhesive layer configured to encapsulate the first light-emitting assembly, and the shape of the first adhesive layer is a shape of a contact surface between the light-transmissive adhesive layer and the first light-emitting assembly;
determining a shape of a second adhesive layer corresponding to the second light-emitting assembly based on a second position of the second light-emitting surface in the light-transmissive adhesive layer, wherein the second adhesive layer is the light-transmissive adhesive layer configured to encapsulate the second light-emitting assembly, and the shape of the second adhesive layer is a shape of a contact surface between the light-transmissive adhesive layer and the second light-emitting assembly;
cutting the light-transmissive adhesive layer based on the shape of the first adhesive layer and the shape of the second adhesive layer to obtain the first adhesive layer, the second adhesive layer and an adhesive flow channel; the adhesive flow channel is located at outer sides of the first adhesive layer and the second adhesive layer except the first light-emitting surface and the second light-emitting surface; and
forming a third adhesive layer in the adhesive flow channel by a second molding process; wherein the third adhesive layer is the opaque adhesive layer.

According to a second aspect of the present disclosure, the present disclosure provides an LED bead, including:
an insulating base;
a plurality of pins, the plurality of pins being disposed on the insulating base;
a first light-emitting assembly, the first light-emitting assembly including a first light-emitting chipset and a first driving chip, the first light-emitting chipset and the first driving chip being respectively disposed on the pins and electrically connected to the pins, and the first driving chip being electrically connected to the first light-emitting chipset;
a second light-emitting assembly, the second light-emitting assembly including a second light-emitting chipset and a second driving chip, the second light-emitting chipset and the second driving chip being respectively disposed on the pins and electrically connected to the pins, and the second driving chip being electrically connected to the second light-emitting chipset; and
encapsulation adhesive, the encapsulation adhesive being configured to encapsulate the first light-emitting assembly and the second light-emitting assembly, the encapsulation adhesive including at least one first light-emitting surface and at least one second light-emitting surface, the first light-emitting surface being disposed relative to the first light-emitting assembly, and the second light-emitting surface being disposed relative to the second light-emitting assembly;
wherein the first driving chip is configured to control the first light-emitting chipset to emit light via the first light-emitting surface, and the second driving chip is configured to control the second light-emitting chipset to emit light via the second light-emitting surface.

In the LED bead according to an embodiment of the present disclosure, the encapsulation adhesive includes: a first adhesive layer, the first adhesive layer being configured to encapsulate the first light-emitting assembly; the first adhesive layer including the first light-emitting surface; a second adhesive layer, the second adhesive layer being configured to encapsulate the second light-emitting assembly; the second adhesive layer including the second light-emitting surface; a third adhesive layer, the third adhesive layer being formed on outer sides of the first adhesive layer and the second adhesive layer except the first light-emitting surface and the second light-emitting surface; wherein the first adhesive layer and the second adhesive layer are light-transmissive adhesive layers, and the third adhesive layer is an opaque adhesive layer.

According to a third aspect of the present disclosure, the present disclosure provides an electronic device including the LED bead provided in any embodiment of the present disclosure.

The technical solutions provided in the embodiments of the present disclosure may include the following beneficial effects: the present disclosure designs an LED bead, a preparation method and an electronic device. The LED bead includes an insulating base, a plurality of pins, a first light-emitting assembly, a second light-emitting assembly and encapsulation adhesive. The plurality of pins are disposed on the insulating base. The first light-emitting assembly includes a first light-emitting chipset and a first driving chip. The first light-emitting chipset and the first driving chip are respectively disposed on the pins and electrically connected to the pins, and the first driving chip is electrically connected to the first light-emitting chipset. The second light-emitting assembly includes a second light-emitting chipset and a second driving chip. The second light-emitting chipset and the second driving chip are respectively disposed on the pins and electrically connected to the pins, and the second driving chip is electrically connected to the second light-emitting chipset. The encapsulation adhesive is configured to encapsulate the first light-emitting assembly and the second light-emitting assembly. The encapsulation adhesive includes at least one first light-emitting surface and at least one second light-emitting surface. The first light-emitting surface is disposed relative to the first light-emitting assembly, and the second light-emitting surface is disposed relative to the second light-emitting assembly. The first driving chip is configured to control the first light-emitting chipset to emit light via the first light-emitting surface, and the second driving chip is configured to control the second light-emitting chipset to emit light via the second light-emitting surface.

In the LED bead provided by the present disclosure, the first light-emitting assembly and the second light-emitting assembly on two sides of the LED bead form corresponding first light-emitting surface and second light-emitting surface with the encapsulation adhesive, so that light emission of the first light-emitting surface and the second light-emitting surface can be respectively controlled, thereby achieving flexible dual-sided light emission of the LED bead and enabling the miniaturization of an electronic device designed based on the LED bead.

It should be understood that the above general description and the following detailed description are exemplary and explanatory only and are not restrictive of the present disclosure.

### BRIEF DESCRIPTION OF THE DRAWINGS

To more clearly expound the technical solutions of embodiments of the present disclosure, a brief description will be provided below for the drawings that are necessary for illustrating the embodiments. Obviously, the drawings described below are provided for some of the embodiments of the present disclosure, and based on such drawings, those having ordinary skill in the art may obtain other drawings without creative effort.

FIG. 1 is a schematic structural view showing an LED bead according to one embodiment of the present disclosure;

FIG. 2 is a second schematic structural view showing an LED bead according to one embodiment of the present disclosure;

FIG. 3 is a third schematic structural view showing an LED bead according to one embodiment of the present disclosure;

FIG. 4 is an exploded schematic view showing an LED bead according to one embodiment of the present disclosure;

FIG. 5 is a fourth schematic structural view showing an LED bead according to one embodiment of the present disclosure;

FIG. 6 is a fifth schematic structural view showing an LED bead according to one embodiment of the present disclosure;

FIG. 7 is a schematic flow chart showing steps showing a method for preparing an LED bead according to one embodiment of the present disclosure;

FIG. 8 is a schematic structural view showing an electronic device according to one embodiment of the present disclosure.

### DESCRIPTION OF REFERENCE SIGNS

100, electronic device;
10, LED bead;
11, insulating base;
12, pin; 121, first power pin; 1211, die-bonding portion of the first power pin; 1212, soldering portion of the first power pin; 122, first ground pin; 1221, die-bonding portion of the first ground pin; 1222, soldering portion of the first ground pin; 123, first signal input pin; 1231, die-bonding portion of the first signal input pin; 1232, soldering portion of the first signal input pin; 124, first signal output pin; 1241, die-bonding portion of the first signal output pin; 1242, soldering portion of the first signal output pin; 125, second power pin; 1251, die-bonding portion of the second power pin; 1252, soldering portion of the second power pin; 126, second ground pin; 1261, die-bonding portion of the second ground pin; 1262, soldering portion of the second ground pin; 127, second signal input pin; 1271, die-bonding portion of the second signal input pin; 1272, soldering portion of the second signal input pin; 128, second signal output pin; 1281, die-bonding portion of the second signal output pin; 1282, soldering portion of the second signal output pin;
13, first light-emitting assembly; 131, first light-emitting chipset; 132, first driving chip;
14, second light-emitting assembly; 141, second light-emitting chipset; 142, second driving chip;
15, encapsulation adhesive; 151, first adhesive layer; 152, second adhesive layer; 153, third adhesive layer;
16, soldering material.

It should be understood that the above general description and the following detailed description are exemplary and explanatory only, and are not intended to limit the present disclosure.

### DETAILED DESCRIPTION

The technical solutions in embodiments of the present disclosure will be clearly and completely described below with reference to the drawings in the embodiments of the present disclosure, and it is obvious that the described embodiments are a part of the embodiments of the present disclosure, but not all of the embodiments. Based on the embodiments of the present disclosure, all other embodiments obtained by those having ordinary skill in the art without any inventive work belong to the scope of the present disclosure.

It should also be understood that the terminology used in the description of the present disclosure is for the purpose of describing particular embodiments. In the description of the present disclosure, it should be understood that the terms “center”, “longitudinal”, “lateral”, “length”, “width”, “thickness”, “upper”, “lower”, “front”, “back”, “left”, “right”, “vertical”, “horizontal”, “top”, “bottom”, “inner”, “outer”, “center”, “clockwise”, “counterclockwise”, and the like refer to orientations or positional relationships based on orientations or positional relationships shown in the accompanying drawings, and are intended only to facilitate the description of the present application and to simplify the description, rather than indicating or implying that the device or element must have specific orientations or be constructed and operated in specific orientations. Therefore, the terms should not be understood as limitations on the present disclosure. Furthermore, the terms “first” and “second” are used only for descriptive purposes and should not be understood as indicating or implying relative importance or implying the number of the technical features indicated. Thus, features defined with “first” or “second” may explicitly or implicitly include one or more of the described features. In the description of the present disclosure, the terms “a plurality of”, and “more than one” mean two or more, unless otherwise expressly and specifically limited.

Some embodiments of the present disclosure will be described in detail below with reference to the drawings. In the case of no conflict, the following embodiments and features in the embodiments may be combined with each other.

LED beads have been widely used in the lighting and display industries due to their advantages such as energy saving, power saving, high efficiency, fast response time, long service life, mercury-free and environmental friendliness, and have become one of the most prominent products in recent years.

However, when LED beads are used in relatively narrow areas of electronic products, such as in fans with an annular housing, existing LED beads can only illuminate one side of the fan, which limits the functions of the fan. Meanwhile, with the miniaturization of existing LED bead products—such as during the research and development of ultra-thin screens like grid screens—LED beads need to be arranged in pairs to achieve dual-sided light emission of the products, which restricts further miniaturization of LED products.

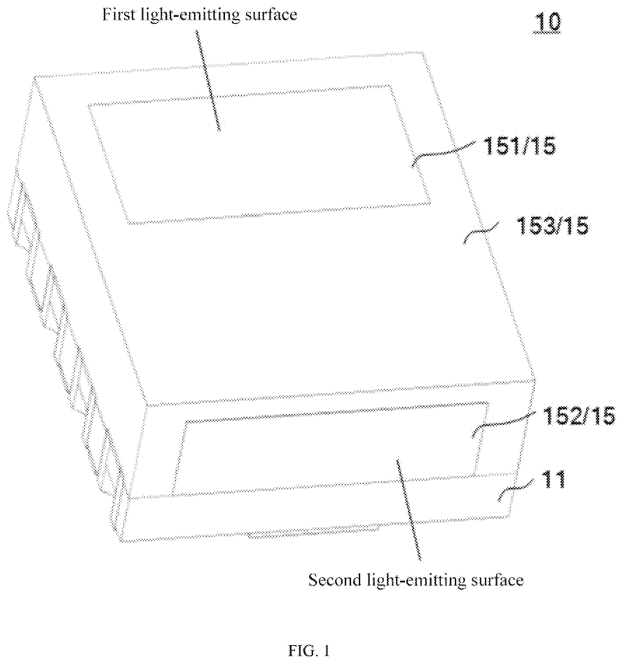

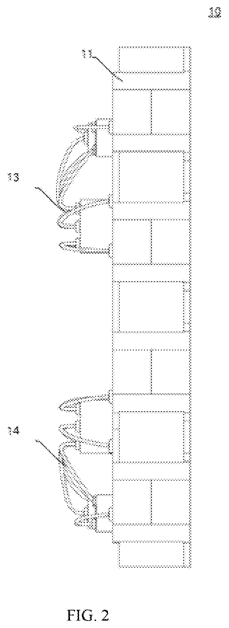

To solve the above problems, referring to FIGS. 1 to 6, as shown in FIGS. 1 to 6, the present disclosure provides an LED bead 10, including an insulating base 11, a plurality of pins 12, a first light-emitting assembly 13, a second light-emitting assembly 14 and encapsulation adhesive 15. The plurality of pins 12 are disposed on the insulating base 11. The first light-emitting assembly 13 includes a first light-emitting chipset 131 and a first driving chip 132. The first light-emitting chipset 131 and the first driving chip 132 are respectively disposed on the pins 12 and electrically connected to the pins 12, and the first driving chip 132 is electrically connected to the first light-emitting chipset 131. The second light-emitting assembly 14 includes a second light-emitting chipset 141 and a second driving chip 142. The second light-emitting chipset 141 and the second driving chip 142 are respectively disposed on the pins 12 and electrically connected to the pins 12, and the second driving chip 142 is electrically connected to the second light-emitting chipset 141. The encapsulation adhesive 15 is configured to encapsulate the first light-emitting assembly 13 and the second light-emitting assembly 14. The encapsulation adhesive 15 includes at least one first light-emitting surface and at least one second light-emitting surface. The first light-emitting surface is disposed relative to the first light-emitting assembly 13, and the second light-emitting surface is disposed relative to the second light-emitting assembly 14. The first driving chip 132 is configured to control the first light-emitting chipset 131 to emit light via the first light-emitting surface. The second driving chip 142 is configured to control the second light-emitting chipset 141 to emit light via the second light-emitting surface.

Specifically, in the LED bead 10 provided by the present disclosure, the first light-emitting assembly 13 and the second light-emitting assembly 14 on two sides of the LED bead 10 form corresponding first light-emitting surface and second light-emitting surface with the encapsulation adhesive 15, so that light can be emitted via the first light-emitting surface and the second light-emitting surface respectively, thereby achieving flexible dual-sided light emission of the LED bead 10, and enabling the miniaturization of an electronic device 100 designed based on the LED bead 10.

In some embodiments, referring to FIG. 1 and FIG. 4, the encapsulation adhesive 15 includes: a first adhesive layer 151, a second adhesive layer 152 and a third adhesive layer 153, the first adhesive layer 151 is configured to encapsulate the first light-emitting assembly 13; the first adhesive layer 151 includes the first light-emitting surface; the second adhesive layer 152 is configured to encapsulate the second light-emitting assembly 14; the second adhesive layer 152 includes the second light-emitting surface; the third adhesive layer 153 is formed on outer sides of the first adhesive layer 151 and the second adhesive layer 152 except the first light-emitting surface and the second light-emitting surface. The first adhesive layer 151 and the second adhesive layer 152 are light-transmissive adhesive layers or diffusion adhesive layers, and the third adhesive layer 153 is an opaque adhesive layer.

By using either a light-transmissive adhesive layer or a diffusion adhesive layer for the first adhesive layer 151 and the second adhesive layer 152, and using an opaque adhesive layer for the third adhesive layer 153, the first adhesive layer 151 and the second adhesive layer 152 can expose the first light-emitting surface and the second light-emitting surface, thereby achieving control over the light-emitting surfaces on two sides of the LED bead 10.

In some embodiments, the first light-emitting surface is located on a top surface or a side surface of the first adhesive layer 151, and the top surface corresponds to the insulating base 11.

In some embodiments, the second light-emitting surface is located on a top surface or a side surface of the second adhesive layer 152, and the top surface corresponds to the insulating base 11.

It should be noted that specific positions of the first light-emitting surface and the second light-emitting surface are selected according to an actual position where the product needs to emit light, and the embodiment of the present disclosure does not limit the positions of the first light-emitting surface and the second light-emitting surface.

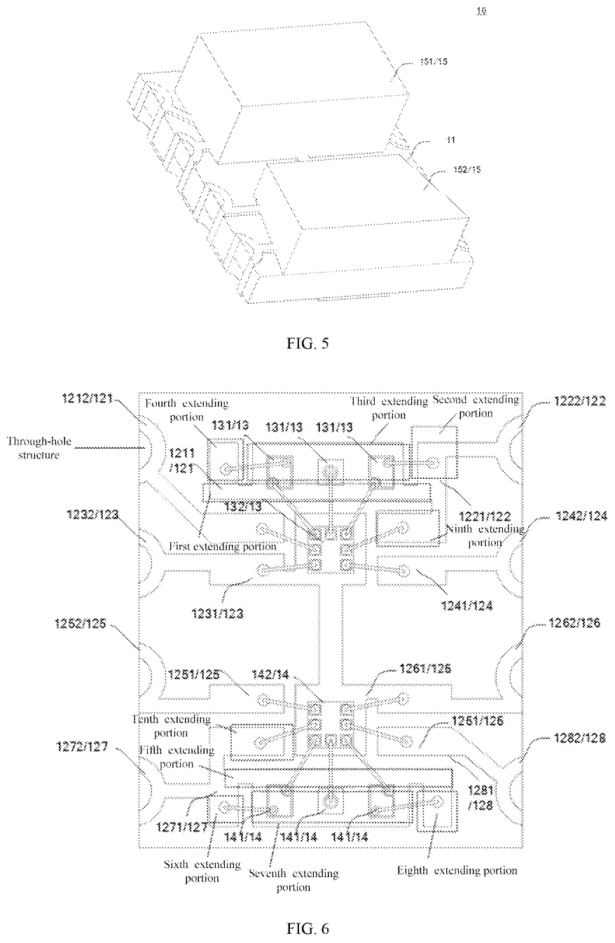

As shown in FIG. 5, the present disclosure can set the positions of the first light-emitting surface and the second light-emitting surface on the top surface or the side surface respectively according to actual needs, so as to improve the flexibility of the LED bead 10.

In some embodiments, the first light-emitting surface and the second light-emitting surface are rectangular in shape. Thus, light from the first light-emitting assembly 13 and the second light-emitting assembly 14 can be emitted uniformly.

It should be noted that the shapes of the first light-emitting surface and the second light-emitting surface can also be any shape such as square, circle or rhombus, and the embodiment of the present disclosure does not limit the types of the first light-emitting surface and the second light-emitting surface.

In some embodiments, the first light-emitting surface is located on the top surface of the first adhesive layer 151, and a contact surface between the first adhesive layer 151 and the first light-emitting assembly 13 is rectangular in shape; or, the first light-emitting surface is located on the side surface of the first adhesive layer 151, and a contact surface between the first adhesive layer 151 and the first light-emitting assembly 13 is trapezoidal in shape. The second light-emitting surface is located on the top surface of the second adhesive layer 152, and a contact surface between the second adhesive layer 152 and the second light-emitting assembly 14 is rectangular in shape; or, the second light-emitting surface is located on the side surface of the second adhesive layer 152, and a contact surface between the second adhesive layer 152 and the second light-emitting assembly 14 is trapezoidal in shape.

When the first light-emitting surface or the second light-emitting surface is trapezoidal, as shown in FIG. 5, the trapezoid is inclined inward and downward at an angle, so that light from the first light-emitting assembly 13 and the second light-emitting assembly 14 can be better emitted via the corresponding light-emitting surfaces.

In some embodiments, as shown in FIG. 6, the pin 12 on which the first driving chip 132 is disposed is connected to the pin 12 on which the second driving chip 142 is disposed. Furthermore, wiring of the LED bead 10 can be facilitated and a problem of cold solder joints caused by single-sided insufficient solder can be prevented. Meanwhile, the embodiment of the present disclosure does not limit the types of the pins 12 on which the first driving chip 132 and the second driving chip 142 are disposed, that is, does not limit the types of the interconnected pins 12.

In some embodiments, the plurality of pins 12 include four sets of pin pairs, which are respectively a first pin pair, a second pin pair, a third pin pair and a fourth pin pair, and the pins 12 in each pin pair are relatively distributed on the insulating base 11. The first pin pair includes a first power pin 121 and a first ground pin 122, the first light-emitting chipset 131 and the first driving chip 132 are electrically connected to the first power pin 121, and the first driving chip 132 is electrically connected to the first ground pin 122. The second pin pair includes a first signal input pin 123 and a first signal output pin 124, and the first driving chip 132 is electrically connected to the first signal input pin 123 and the first signal output pin 124. The third pin pair includes a second signal input pin 127 and a second signal output pin 128, and the second driving chip 142 is electrically connected to the second signal input pin 127 and the second signal output pin 128. The fourth pin pair includes a second power pin 125 and a second ground pin 126, the second light-emitting chipset 141 and the second driving chip 142 are electrically connected to the second power pin 125, and the second driving chip 142 is electrically connected to the second ground pin 126. Furthermore, standardized layout of the LED bead 10 can be achieved by arrangement of the plurality of pin pairs.

In some embodiments, the insulating base 11 includes a first end surface. The first ground pin 122, the first power pin 121, the first signal input pin 123, the first signal output pin 124, the second ground pin 126, the second power pin 125, the second signal input pin 127 and the second signal output pin 128 have die-bonding portions formed on the first end surface and soldering portions formed on other end surfaces of the insulating base 11. The first light-emitting assembly 13 is disposed on the die-bonding portion of any one of the first ground pin 122, the first power pin 121, the first signal input pin 123 and the first signal output pin 124. The second light-emitting assembly 14 is disposed on the die-bonding portion of any one of the second ground pin 126, the second power pin 125, the second signal input pin 127 and the second signal output pin 128. At least part of the soldering portion is formed with a through-hole structure.

In some embodiments, each of the first light-emitting chipset 131 and the second light-emitting chipset 141 includes a plurality of light-emitting chips. The light-emitting chips of the first light-emitting chipset 131 and the light-emitting chips of the second light-emitting chipset 141 are respectively disposed on the die-bonding portion at equal intervals.

In some embodiments, the first driving chip 132 and the first light-emitting chipset 131 are respectively disposed on the die-bonding portion of any one of the first ground pin 122, the first power pin 121, the first signal input pin 123 and the first signal output pin 124.

In some embodiments, the second driving chip 142 and the second light-emitting chipset 141 are respectively disposed on the die-bonding portion of any one of the second ground pin 126, the second power pin 125, the second signal input pin 127 and the second signal output pin 128.

In some embodiments, as shown in FIG. 6, the die-bonding portion on which the first light-emitting chipset 131 is disposed includes a first extending portion and a second extending portion perpendicular to the first extending portion. The first extending portion extends toward a direction of the other pin 12 in the pin pair where the die-bonding portion carrying the first light-emitting chipset 131 is located, and is formed with a third extending portion and a fourth extending portion spaced apart from the second extending portion. The die-bonding portion on which the second light-emitting chipset 141 is disposed includes a fifth extending portion and a sixth extending portion perpendicular to the fifth extending portion. The fifth extending portion extends toward a direction of the other pin 12 in the pin pair where the die-bonding portion carrying the second light-emitting chipset 141 is located, and is formed with a seventh extending portion and an eighth extending portion spaced apart from the sixth extending portion. The first light-emitting chipset 131 is disposed in the second extending portion, and the plurality of light-emitting chips in the first light-emitting chipset 131 are electrically connected to the second extending portion and the fourth extending portion respectively. The second light-emitting chipset 141 is disposed in the seventh extending portion, and the plurality of light-emitting chips in the second light-emitting chipset 141 are electrically connected to the sixth extending portion and the eighth extending portion respectively.

In some embodiments, as shown in FIG. 6, the die-bonding portion on which the first light-emitting chipset 131 is disposed further includes a ninth extending portion disposed relative to the second extending portion, and the first driving chip 132 is electrically connected to the ninth extending portion. The die-bonding portion on which the second light-emitting chipset 141 is disposed further includes a tenth extending portion disposed relative to the sixth extending portion, and the second driving chip 142 is electrically connected to the tenth extending portion.

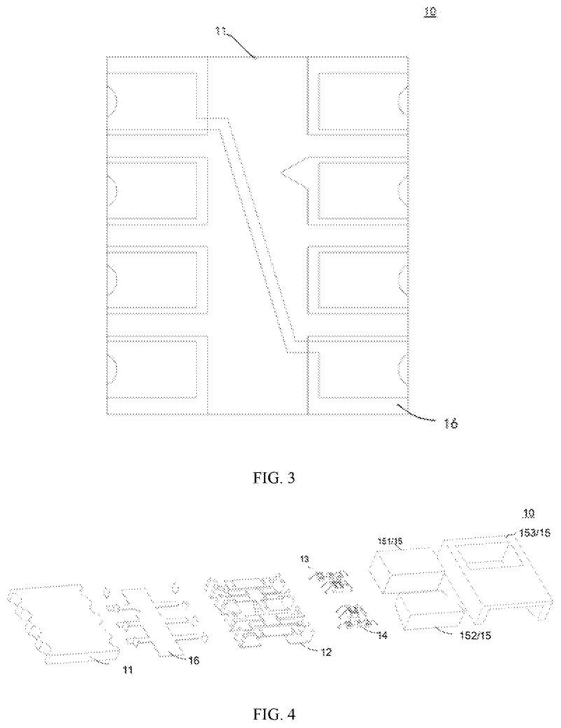

In some embodiments, as shown in FIG. 3, a back surface of the LED bead 10 is coated with a soldering material 16, such as green oil, outside the pins to ensure smooth connection of the pins.

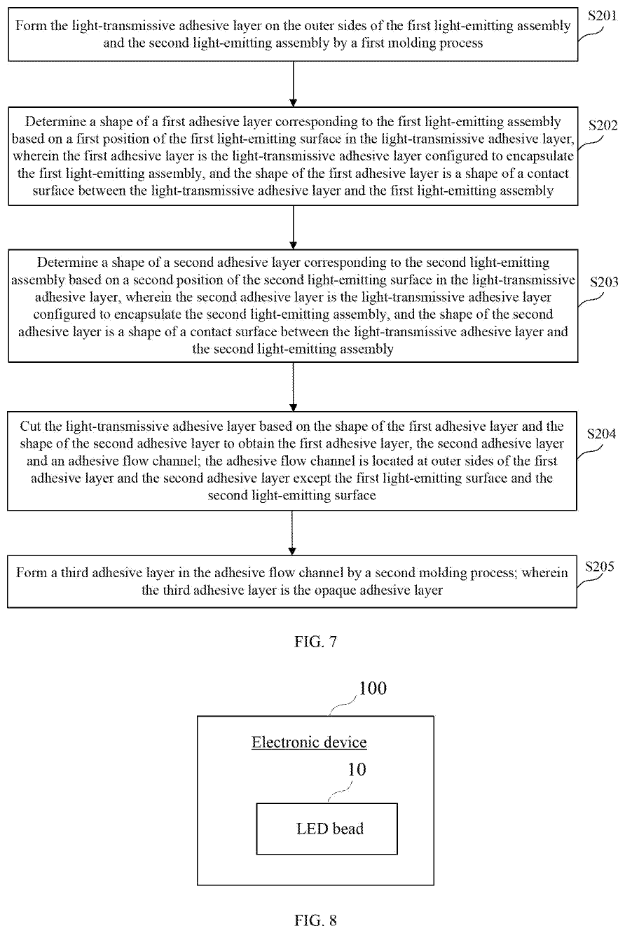

Referring to FIG. 7, FIG. 7 is a method for preparing an LED bead according to one embodiment of the present disclosure, which is configured to manufacture the LED bead shown in FIGS. 1 to 6. The LED bead includes an insulating base, a plurality of pins, a first light-emitting assembly, a second light-emitting assembly and encapsulation adhesive. The plurality of pins are disposed on the insulating base. The first light-emitting assembly includes a first light-emitting chipset and a first driving chip. The first light-emitting chipset and the first driving chip are respectively disposed on the pins and electrically connected to the pins, and the first driving chip is electrically connected to the first light-emitting chipset. The second light-emitting assembly includes a second light-emitting chipset and a second driving chip. The second light-emitting chipset and the second driving chip are respectively disposed on the pins and electrically connected to the pins, and the second driving chip is electrically connected to the second light-emitting chipset. The encapsulation adhesive is configured to encapsulate the first light-emitting assembly and the second light-emitting assembly. The encapsulation adhesive includes a first light-emitting surface and a second light-emitting surface. The first light-emitting surface is disposed relative to the first light-emitting assembly, and the second light-emitting surface is disposed relative to the second light-emitting assembly. The encapsulation adhesive includes a light-transmissive adhesive layer and an opaque adhesive layer.

As shown in FIG. 7, the method includes steps S201 to S207.

S201: Form the light-transmissive adhesive layer on the outer sides of the first light-emitting assembly and the second light-emitting assembly by a first molding process.

By the first molding process, the method can form a corresponding light-transmissive adhesive layer on the outer sides of the first light-emitting assembly and the second light-emitting assembly. Of course, a diffusion adhesive layer can also be formed according to actual needs, so that light from the first light-emitting assembly and the second light-emitting assembly can be emitted outward.

S202: Determine a shape of a first adhesive layer corresponding to the first light-emitting assembly based on a first position of the first light-emitting surface in the light-transmissive adhesive layer, wherein the first adhesive layer is the light-transmissive adhesive layer configured to encapsulate the first light-emitting assembly, and the shape of the first adhesive layer is a shape of a contact surface between the light-transmissive adhesive layer and the first light-emitting assembly.

S203: Determine a shape of a second adhesive layer corresponding to the second light-emitting assembly based on a second position of the second light-emitting surface in the light-transmissive adhesive layer, wherein the second adhesive layer is the light-transmissive adhesive layer configured to encapsulate the second light-emitting assembly, and the shape of the second adhesive layer is a shape of a contact surface between the light-transmissive adhesive layer and the second light-emitting assembly.

Since not every surface requires a corresponding light-emitting assembly to emit light, the present disclosure determines the shapes of the first adhesive layer and the second adhesive layer according to corresponding positions of the first light-emitting surface and the second light-emitting surface, such as a top surface or a side surface, so as to ensure that the first adhesive layer and the second adhesive layer meeting the requirements can be formed after cutting, thereby improving the light-emitting effect of the LED bead.

S204: Cut the light-transmissive adhesive layer based on the shape of the first adhesive layer and the shape of the second adhesive layer to obtain the first adhesive layer, the second adhesive layer and an adhesive flow channel; the adhesive flow channel is located at outer sides of the first adhesive layer and the second adhesive layer except the first light-emitting surface and the second light-emitting surface.

The first adhesive layer and the second adhesive layer are cut based on corresponding shapes, and the corresponding adhesive flow channel is reserved at the same time to provide an adhesive flow opening for a subsequent second molding process.

S205: Form a third adhesive layer in the adhesive flow channel by a second molding process; wherein the third adhesive layer is the opaque adhesive layer.

By the second molding process, the opaque third adhesive layer can be formed on outer sides of the first adhesive layer and the second adhesive layer except the corresponding first light-emitting surface and second light-emitting surface, so that the LED bead can smoothly emit light outward according to a preset surface, thereby improving the flexibility of the LED bead.

In some embodiments, the first light-emitting surface is located on a top surface or a side surface of the first adhesive layer; and/or the second light-emitting surface is located on a top surface or a side surface of the second adhesive layer; the top surface corresponds to the insulating base.

In some embodiments, the first light-emitting surface and the second light-emitting surface are rectangular in shape.

In some embodiments, the first light-emitting surface is located on the top surface of the first adhesive layer, and a contact surface between the first adhesive layer and the first light-emitting assembly is rectangular in shape; or the first light-emitting surface is located on the side surface of the first adhesive layer, and a contact surface between the first adhesive layer and the first light-emitting assembly is trapezoidal in shape. The second light-emitting surface is located on the top surface of the second adhesive layer, and a contact surface between the second adhesive layer and the second light-emitting assembly is rectangular in shape; or the second light-emitting surface is located on the side surface of the second adhesive layer, and a contact surface between the second adhesive layer and the second light-emitting assembly is trapezoidal in shape.

Referring to FIG. 8, FIG. 8 is a schematic structural view showing an electronic device 100 according to one embodiment of the present disclosure. As shown in FIG. 8, the electronic device 100 includes the LED bead 10 provided in any embodiment of the present disclosure, thereby enabling the miniaturization of the electronic device 100.

In some embodiments, the electronic device 100 is any device such as a fan or a screen, and the embodiment of the present disclosure does not limit the type of the electronic device 100.

In some embodiments, the electronic device 100 includes a plurality of LED beads 10, and the plurality of LED beads can be connected at intervals in the electronic device 100, or a corresponding connection method can be set according to needs.

In the description of the present disclosure, it should be noted that, unless otherwise clearly specified and limited, the terms “installed”, “connected”, “coupled” should be understood in a broad sense, for example, may be a fixed connection, or may be a detachable connection, or may be an integral connection. It can be a mechanical connection or an electric connection. It can be a direct connection, or an indirect connection through an intermediate medium, or it can be internal communication between two elements or an interaction relation between the two elements. For those having ordinary skill in the art, the specific meaning of the above terms in the present disclosure can be understood according to specific situations.

In the present disclosure, unless otherwise clearly specified and limited, a first feature being “on” or “under” a second feature” may include a direct contact between the first feature and the second feature, or may include an additional feature contact between the first feature and the second feature instead of the direct contact. Moreover, the first feature being “above”, “on top of” the second feature includes the first feature being directly above and diagonally above the second feature, or only indicating that a horizontal height of the first feature is higher than a horizontal height of the second feature. The first feature being “under”, “below” and “on a lower side” of the second feature includes the first feature directly under and diagonally under the second feature, or only indicates that a horizontal height of the first feature is less than a horizontal height of the second feature.

The above disclosure provides different embodiments or examples for implementing different structures of the present disclosure. In order to simplify disclosure of the present disclosure, components and arrangements of specific examples are described above. Of course, they are only examples and are not intended to limit the present disclosure. In addition, the present disclosure may repeat reference numbers and/or reference letters in different examples, such repetitions being for simplicity and clarity, which do not indicate the relationship between the various embodiments and/or arrangements being discussed. In addition, the present disclosure provides examples of various specific processes and materials, but those having ordinary skill in the art can recognize the application of other processes and/or use of other materials.

In the description of the specification, terms “one embodiment”, “some embodiments”, “exemplary embodiments”, “for example”, “specific example”, or “such as” means that specific method steps, features, structures, materials or characteristics described in combination with one embodiment or one example are included in at least one embodiment or one example of the present application. In the specification, the illustrative expressions of the above terms do not necessarily refer to the same embodiment or example. Moreover, the specific method steps, features, structures, materials, or features described may be combined in a suitable manner in any one or more embodiments or examples.

What is claimed is:

1. A method for preparing an LED bead, for manufacturing an LED bead, wherein the LED bead comprises an insulating base, a plurality of pins, a first light-emitting assembly, a second light-emitting assembly and encapsulation adhesive; the plurality of pins are disposed on the insulating base; the first light-emitting assembly comprises a first light-emitting chipset and a first driving chip, the first light-emitting chipset and the first driving chip are respectively disposed on the pins and electrically connected to the pins, and the first driving chip is electrically connected to the first light-emitting chipset; the second light-emitting assembly comprises a second light-emitting chipset and a second driving chip, the second light-emitting chipset and the second driving chip are respectively disposed on the pins and electrically connected to the pins, and the second driving chip is electrically connected to the second light-emitting chipset; the encapsulation adhesive is configured to encapsulate the first light-emitting assembly and the second light-emitting assembly, the encapsulation adhesive comprises a first light-emitting surface and a second light-emitting surface, the first light-emitting surface is disposed relative to the first light-emitting assembly, the second light-emitting surface is disposed relative to the second light-emitting assembly, and the encapsulation adhesive comprises a light-transmissive adhesive layer and an opaque adhesive layer; the method comprises:
forming the light-transmissive adhesive layer on the outer sides of the first light-emitting assembly and the second light-emitting assembly by a first molding process;
determining a shape of a first adhesive layer corresponding to the first light-emitting assembly based on a first position of the first light-emitting surface in the light-transmissive adhesive layer, wherein the first adhesive layer is the light-transmissive adhesive layer configured to encapsulate the first light-emitting assembly, and the shape of the first adhesive layer is a shape of a contact surface between the light-transmissive adhesive layer and the first light-emitting assembly;
determining a shape of a second adhesive layer corresponding to the second light-emitting assembly based on a second position of the second light-emitting surface in the light-transmissive adhesive layer, wherein the second adhesive layer is the light-transmissive adhesive layer configured to encapsulate the second light-emitting assembly, and the shape of the second adhesive layer is a shape of a contact surface between the light-transmissive adhesive layer and the second light-emitting assembly;
cutting the light-transmissive adhesive layer based on the shape of the first adhesive layer and the shape of the second adhesive layer to obtain the first adhesive layer, the second adhesive layer and an adhesive flow channel; the adhesive flow channel is located at outer sides of the first adhesive layer and the second adhesive layer except the first light-emitting surface and the second light-emitting surface; and
forming a third adhesive layer in the adhesive flow channel by a second molding process; wherein the third adhesive layer is the opaque adhesive layer.

2. The method according to claim 1, wherein the first light-emitting surface is located on a top surface or a side surface of the first adhesive layer; or
the second light-emitting surface is located on a top surface or a side surface of the second adhesive layer; the top surface corresponds to the insulating base.

3. The method according to claim 2, wherein the first light-emitting surface and the second light-emitting surface are rectangular in shape.

4. The method according to claim 2, wherein the first light-emitting surface is located on the top surface of the first adhesive layer, and a contact surface between the first adhesive layer and the first light-emitting assembly is rectangular in shape; or the first light-emitting surface is located on the side surface of the first adhesive layer, and a contact surface between the first adhesive layer and the first light-emitting assembly is trapezoidal in shape;
the second light-emitting surface is located on the top surface of the second adhesive layer, and a contact surface between the second adhesive layer and the second light-emitting assembly is rectangular in shape; or the second light-emitting surface is located on the side surface of the second adhesive layer, and a contact surface between the second adhesive layer and the second light-emitting assembly is trapezoidal in shape.

5. An LED bead, comprising:
an insulating base;
a plurality of pins, the plurality of pins being disposed on the insulating base;
a first light-emitting assembly, the first light-emitting assembly comprising a first light-emitting chipset and a first driving chip, the first light-emitting chipset and the first driving chip being respectively disposed on the pins and electrically connected to the pins, and the first driving chip being electrically connected to the first light-emitting chipset;
a second light-emitting assembly, the second light-emitting assembly comprising a second light-emitting chipset and a second driving chip, the second light-emitting chipset and the second driving chip being respectively disposed on the pins and electrically connected to the pins, and the second driving chip being electrically connected to the second light-emitting chipset; and
encapsulation adhesive, the encapsulation adhesive being configured to encapsulate the first light-emitting assembly and the second light-emitting assembly, the encapsulation adhesive comprising at least one first light-emitting surface and at least one second light-emitting surface, the first light-emitting surface being disposed relative to the first light-emitting assembly, and the second light-emitting surface being disposed relative to the second light-emitting assembly;
wherein the first driving chip is configured to control the first light-emitting chipset to emit light via the first light-emitting surface, and the second driving chip is configured to control the second light-emitting chipset to emit light via the second light-emitting surface.

6. The LED bead according to claim 5, wherein the encapsulation adhesive comprises:
a first adhesive layer, the first adhesive layer being configured to encapsulate the first light-emitting assembly; the first adhesive layer comprising the first light-emitting surface;
a second adhesive layer, the second adhesive layer being configured to encapsulate the second light-emitting assembly; the second adhesive layer comprising the second light-emitting surface;
a third adhesive layer, the third adhesive layer being formed on outer sides of the first adhesive layer and the second adhesive layer except the first light-emitting surface and the second light-emitting surface;
wherein the first adhesive layer and the second adhesive layer are light-transmissive adhesive layers, and the third adhesive layer is an opaque adhesive layer.

7. The LED bead according to claim 6, wherein the first light-emitting surface is located on a top surface or a side surface of the first adhesive layer; or
the second light-emitting surface is located on a top surface or a side surface of the second adhesive layer; the top surface corresponds to the insulating base.

8. The LED bead according to claim 7, wherein the first light-emitting surface and the second light-emitting surface are rectangular in shape.

9. The LED bead according to claim 7, wherein the first light-emitting surface is located on the top surface of the first adhesive layer, and a contact surface between the first adhesive layer and the first light-emitting assembly is rectangular in shape.

10. The LED bead according to claim 7, wherein the first light-emitting surface is located on the side surface of the first adhesive layer, and a contact surface between the first adhesive layer and the first light-emitting assembly is trapezoidal in shape.

11. The LED bead according to claim 7, wherein the second light-emitting surface is located on the top surface of the second adhesive layer, and a contact surface between the second adhesive layer and the second light-emitting assembly is rectangular in shape.

12. The LED bead according to claim 7, wherein the second light-emitting surface is located on the side surface of the second adhesive layer, and a contact surface between the second adhesive layer and the second light-emitting assembly is trapezoidal in shape.

13. The LED bead according to claim 5, wherein the pin on which the first driving chip is disposed is connected to the pin on which the second driving chip is disposed.

14. The LED bead according to claim 5, wherein the plurality of pins comprise four sets of pin pairs, the four sets of pin pairs being respectively a first pin pair, a second pin pair, a third pin pair and a fourth pin pair, and the pins in each pin pair are relatively distributed on the insulating base; wherein
the first pin pair comprises a first power pin and a first ground pin, the first light-emitting chipset and the first driving chip are electrically connected to the first power pin, and the first driving chip is electrically connected to the first ground pin;
the second pin pair comprises a first signal input pin and a first signal output pin, and the first driving chip is electrically connected to the first signal input pin and the first signal output pin;
the third pin pair comprises a second signal input pin and a second signal output pin, and the second driving chip is electrically connected to the second signal input pin and the second signal output pin;
the fourth pin pair comprises a second power pin and a second ground pin, the second light-emitting chipset and the second driving chip are electrically connected to the second power pin, and the second driving chip is electrically connected to the second ground pin.

15. The LED bead according to claim 14, wherein the insulating base comprises a first end surface, and the first ground pin, the first power pin, the first signal input pin, the first signal output pin, the second ground pin, the second power pin, the second signal input pin and the second signal output pin have die-bonding portions formed on the first end surface and soldering portions formed on other end surfaces of the insulating base;
the first light-emitting assembly is disposed on the die-bonding portion of any one of the first ground pin, the first power pin, the first signal input pin and the first signal output pin;
the second light-emitting assembly is disposed on the die-bonding portion of any one of the second ground pin, the second power pin, the second signal input pin and the second signal output pin, and at least part of the soldering portion is formed with a through-hole structure.

16. The LED bead according to claim 15, wherein each of the first light-emitting chipset and the second light-emitting chipset comprises a plurality of light-emitting chips;
wherein the light-emitting chips of the first light-emitting chipset and the light-emitting chips of the second light-emitting chipset are respectively disposed on the die-bonding portion at equal intervals.

17. The LED bead according to claim 15, wherein
the first driving chip and the first light-emitting chipset are respectively disposed on the die-bonding portion of any one of the first ground pin, the first power pin, the first signal input pin and the first signal output pin;
or the second driving chip and the second light-emitting chipset are respectively disposed on the die-bonding portion of any one of the second ground pin, the second power pin, the second signal input pin and the second signal output pin.

18. The LED bead according to claim 17, wherein the die-bonding portion on which the first light-emitting chipset is disposed comprises a first extending portion and a second extending portion perpendicular to the first extending portion, the first extending portion extends toward a direction of the other pin in the pin pair where the die-bonding portion carrying the first light-emitting chipset is located, and is formed with a third extending portion and a fourth extending portion spaced apart from the second extending portion;
the die-bonding portion on which the second light-emitting chipset is disposed comprises a fifth extending portion and a sixth extending portion perpendicular to the fifth extending portion, the fifth extending portion extends toward a direction of the other pin in the pin pair where the die-bonding portion carrying the second light-emitting chipset is located, and is formed with a seventh extending portion and an eighth extending portion spaced apart from the sixth extending portion;
wherein the first light-emitting chipset is disposed in the second extending portion, and the plurality of light-emitting chips in the first light-emitting chipset are electrically connected to the second extending portion and the fourth extending portion respectively;
the second light-emitting chipset is disposed in the seventh extending portion, and the plurality of light-emitting chips in the second light-emitting chipset are electrically connected to the sixth extending portion and the eighth extending portion respectively.

19. The LED bead according to claim 18, wherein
the die-bonding portion on which the first light-emitting chipset is disposed further comprises a ninth extending portion disposed relative to the second extending portion, and the first driving chip is electrically connected to the ninth extending portion;
the die-bonding portion on which the second light-emitting chipset is disposed further comprises a tenth extending portion disposed relative to the sixth extending portion, and the second driving chip is electrically connected to the tenth extending portion.

20. An electronic device, comprising at least one LED bead, wherein the LED bead comprises:
an insulating base;
a plurality of pins, the plurality of pins being disposed on the insulating base;
a first light-emitting assembly, the first light-emitting assembly comprising a first light-emitting chipset and a first driving chip, the first light-emitting chipset and the first driving chip being respectively disposed on the pins and electrically connected to the pins, and the first driving chip being electrically connected to the first light-emitting chipset;
a second light-emitting assembly, the second light-emitting assembly comprising a second light-emitting chipset and a second driving chip, the second light-emitting chipset and the second driving chip being respectively disposed on the pins and electrically connected to the pins, and the second driving chip being electrically connected to the second light-emitting chipset; and
encapsulation adhesive, the encapsulation adhesive being configured to encapsulate the first light-emitting assembly and the second light-emitting assembly, the encapsulation adhesive comprising at least one first light-emitting surface and at least one second light-emitting surface, the first light-emitting surface being disposed relative to the first light-emitting assembly, and the second light-emitting surface being disposed relative to the second light-emitting assembly;
wherein the first driving chip is configured to control the first light-emitting chipset to emit light via the first light-emitting surface, and the second driving chip is configured to control the second light-emitting chipset to emit light via the second light-emitting surface.
